(19) United States
(12) Patent Application Publication
(10) Pub. No.: US 2009/0115013 A1
(43) Pub. Date: May 7, 2009

(54) Image Sensor and Method for Manufacturing the Same

(76) Inventor: Jong Doo Kim, Eumseong-gun (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/239,909

(22) Filed: Sep. 29, 2008

(30) Foreign Application Priority Data
Nov. 5, 2007 (KR) 10-2007-0112161

(51) Int. Cl. H01L 31/0232

(52) U.S. Cl. 257/432; 438/70; 257/E31.127

(57) ABSTRACT

Disclosed is a method for manufacturing an image sensor capable of inhibiting bridge formation between microlenses and minimizing gaps between microlenses. A photodiode and circuitry can be formed on a substrate according to unit pixel. A color filter layer can be formed on the substrate with color filters corresponding to each photodiode. A planarization layer can be formed on the color filter layer, and a groove can be formed in the planarization layer at a boundary between pixels. In one embodiment, the groove can be formed by performing an ashing process with respect to a general photoresist pattern. In another embodiment, the groove can be formed by performing an ashing process with respect to the photoresist pattern for forming the microlens. A microlens can be formed on the planarization layer such that a region of the microlens fills the groove.

### CROSS-REFERENCE TO RELATED APPLICATION

The present application claims the benefit under 35 U.S.C. §119 of Korean Patent Application No. 10-2007-0112161, filed Nov. 5, 2007, which is hereby incorporated by reference in its entirety.

### BACKGROUND

To improve the photo sensitivity of an image sensor, either a fill factor, which is a ratio of a photodiode area to the whole area of the image sensor, must be increased, or a photo-gathering technology is used to change the path of light incident onto an area other than the photodiode area such that the light can be gathered in the photodiode.

A representative example of the photo-gathering technology is to make a microlens.

According to the related art, in order to form a microlens in the process of manufacturing an image sensor, a micro photo process is performed using a special photoresist for a microlens, and then a reflowing process is performed.

However, in the case of employing a microlens using organic material, a gap may be formed between microlenses or a bridge may be generated. If the gap is formed, an unexpected signal may be generated, so that image quality may be degraded. If the bridge is generated, signal noise may be generated, so that image quality may also be degraded.

### BRIEF SUMMARY

Embodiments of the present invention provide an image sensor and a method for manufacturing the same, which can inhibit a bridge formation and minimize a gap between microlenses.

In one embodiment, an image sensor can include a photodiode and circuitry on a substrate arranged according to unit pixels, a color filter layer on the photodiode, a planarization layer on the color filter layer while having a groove at a boundary between pixels, and a microlens on the planarization layer, a portion of the microlens filling the groove.

A method for manufacturing an image sensor according to an embodiment can include forming a photodiode and circuitry on a substrate, forming a color filter layer on the photodiode, forming a planarization layer on the color filter layer, forming a groove in the planarization layer at a boundary between pixels, and forming a microlens on the planarization layer, where a portion of the microlens fills the groove.

According to an image sensor and an image sensor manufacturing method of the embodiments, a groove can be formed in the planarization layer at pixel boundaries, so that bridge formation between microlenses can be inhibited and a gap between the microlenses can be minimized. Thus, image quality can be inhibited from being degraded due to a noise signal.

### BRIEF DESCRIPTION OF THE DRAWINGS

FIG. 1 is a cross-sectional view of an image sensor according to an embodiment of the present invention.

FIGS. 2 to 6 are cross-sectional views illustrating the procedure for manufacturing an image sensor according to a first embodiment.

FIGS. 7 to 10 are cross-sectional views illustrating a procedure for manufacturing an image sensor according to a second embodiment.

### DETAILED DESCRIPTION

Hereinafter, an image sensor and a method for manufacturing the same according to embodiments will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

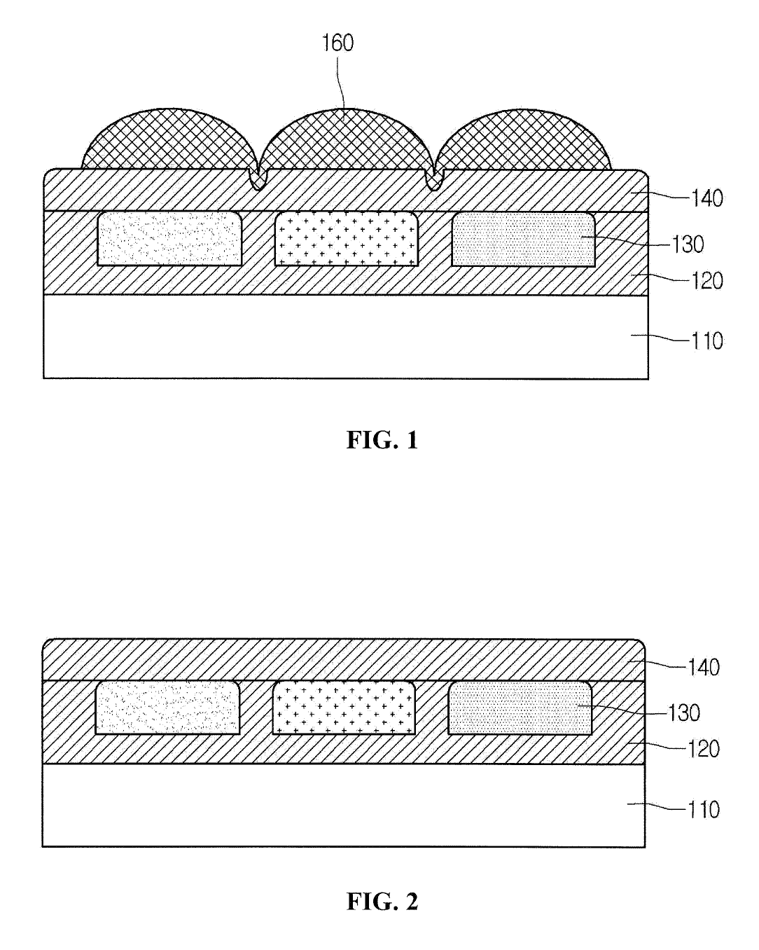

Referring to FIG. 1, an image sensor can include a photodiode (not shown) and circuitry (not shown) formed on a substrate 110 according to unit pixels. A color filter layer 130 can be provided with color filters corresponding to each photodiode. A planarization layer 140 can be formed on the color filter layer 130 while having a groove H in a boundary between pixels, and a microlens 160 can be formed on the planarization layer 140 with portions filling the groove R.

According to embodiments, the groove is formed in the planarization layer 140 at a pixel boundary, so that bridge formation between microlenses can be inhibited and a gap between microlenses can be minimized. Thus, image quality can be inhibited from being degraded due to a noise signal.

By providing a groove at pixel boundaries, edge portions of the microlenses arranged per unit pixel flow into the groove during a reflow process for forming the microlenses. Therefore, bridge formation can be reduced and gaps can be minimized.

Hereinafter, a method for manufacturing an image sensor according to a first embodiment will be described with reference to FIGS. 2 to 6.

Referring to FIG. 2, a photodiode (not shown) and circuitry (not shown) can be formed on a substrate 110 according to unit pixel.

An interlayer dielectric layer 120 can be formed on the substrate 110 including the photodiode.

The interlayer dielectric layer 120 can be prepared in the form of a multilayer. For example, after forming one interlayer dielectric layer, a light blocking layer (not shown) can be formed to inhibit light from being incident into a region other than a photodiode region, and then another interlayer dielectric layer can be formed again. In addition, metal interconnections (not shown) can be formed to provide signal and power lines to the circuitry.

Then, a protective layer (not shown) can be further formed on the interlayer dielectric layer 120 to protect a device from moisture and scratch.

Thereafter, a color filter layer 130 can be formed on the substrate 110. In one embodiment, dyeable resist can be coated on the interlayer dielectric layer 120, and then an exposure and development process can be performed relative to the dyeable resist to form an RGB (red, green, blue) color filter layer 130, which filters light according to wavelengths of the light.

Then, a planarization layer 140 can be formed on the color filter layer 130 to adjust the focal distance and to ensure planarity for forming a lens layer.

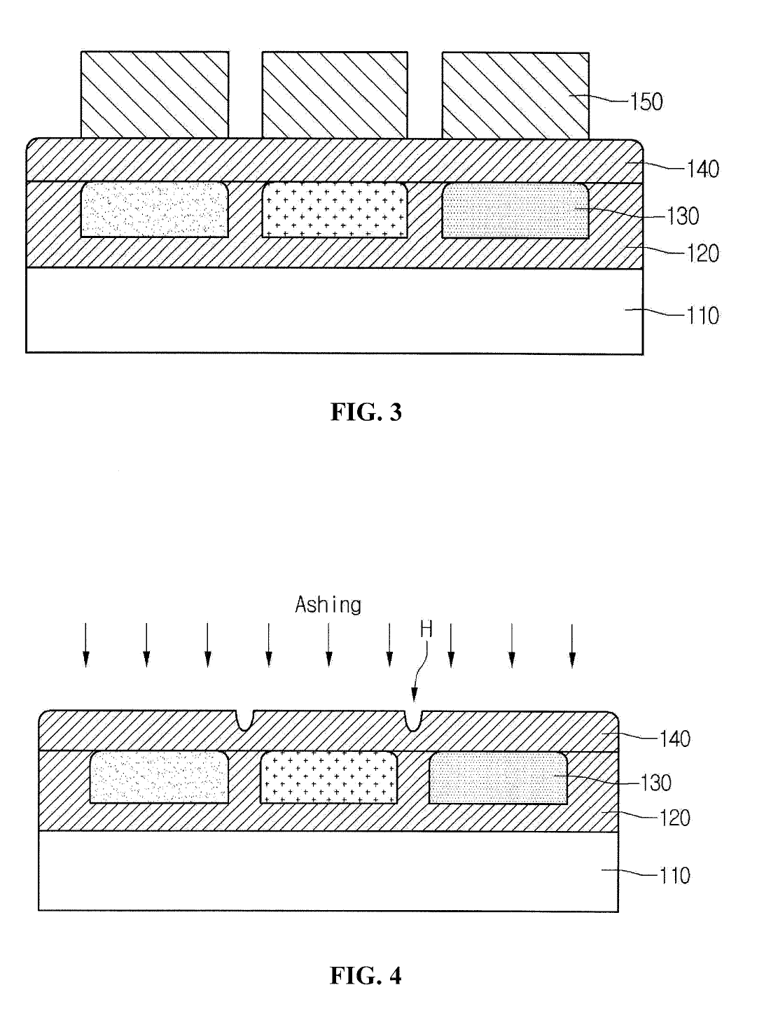

Next, as shown in FIG. 3, a general photoresist layer pattern 150 can be formed on the planarization layer 140 to expose regions of the planarization layer 140 at a boundary between pixels. The general photoresist layer does not refer to a photoresist layer for a microlens.

Referring to FIG. 4, a groove H can be formed in the planarization layer 140 at the boundary between pixels by ashing the general photoresist layer pattern 150. For example, the general photoresist layer pattern 150 can be subject to an ashing process using O₂ plasma. However, embodiments of the present invention are not limited thereto.

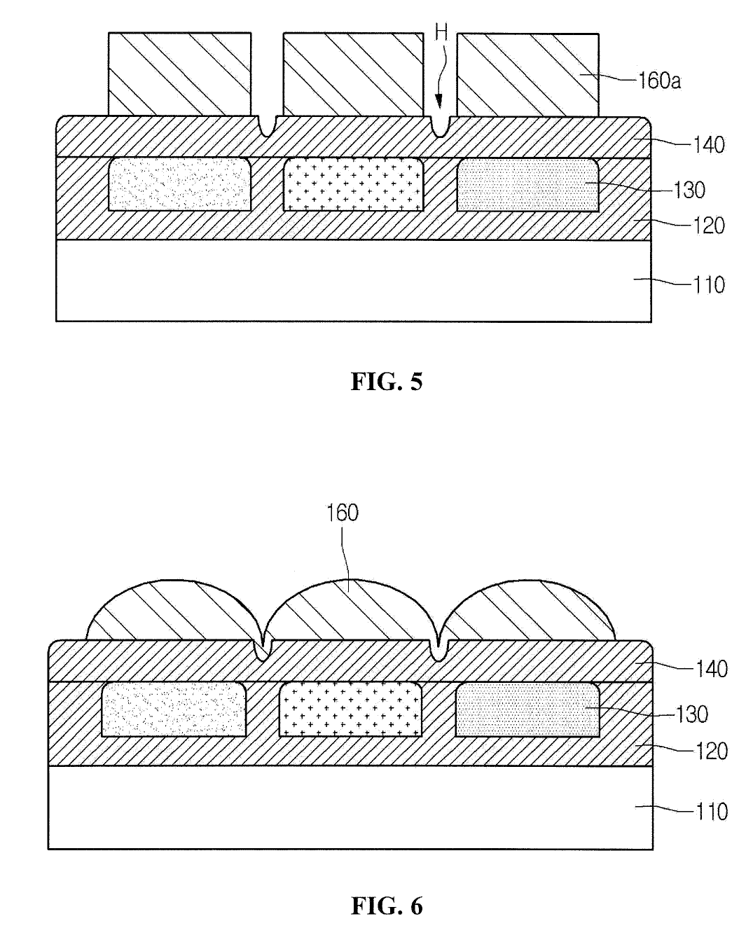

As shown in FIG. 5, a photoresist layer pattern 160a for a microlens can be formed on the planarization layer 140 having the groove H.

As shown in FIG. 6, the photoresist layer pattern 160a can be reflowed to fill the groove H, thereby forming a microlens 160 on the planarization layer 140.

According to the image sensor manufacturing method of the first embodiment, a part between the microlenses is etched by performing an ashing process between the color filter formation process and the reflowing process for forming the microlenses.

The etched part allows the photoresist layer pattern 160a to be filled in the gap between pixels in the subsequent thermal process for reflowing the photoresist layer pattern 160a, so that a bridge between the microlenses can be inhibited and a zero gap can be achieved.

According to an image sensor manufacturing method of the first embodiment, the groove can be formed in the planarization layer at a pixel boundary, so that bridge formation between microlenses can be inhibited and the gap between the microlenses can be minimized. Thus, image quality can be inhibited from being degraded due to a noise signal.

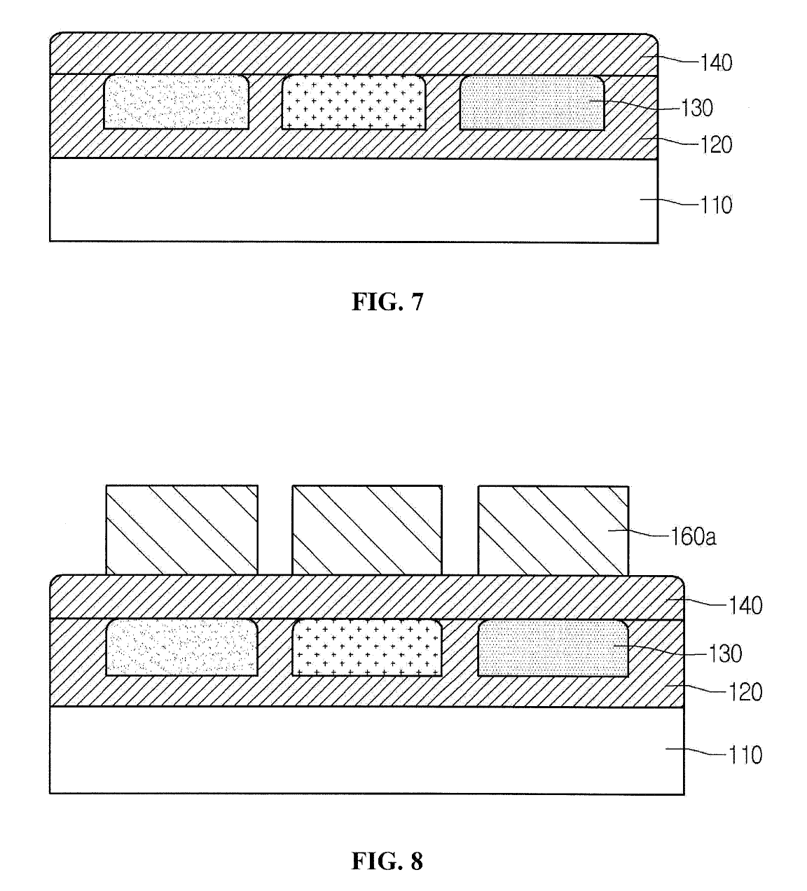

Hereinafter, the method for manufacturing the image sensor according to a second embodiment will be described with reference to FIGS. 7 to 10.

In the first embodiment, the groove is formed by ashing a general photoresist layer. In the second embodiment, the groove can be formed using a photoresist layer for a microlens.

Referring to FIG. 7, image sensor processing steps, including formation of the interlayer dielectric layer 120, the color filter layer 130 and the planarization layer 140 on the substrate 1 10, can be performed similarly to the description of FIG. 2.

Then, as shown in FIG. 8, a photoresist layer pattern 160a for a microlens is formed on the planarization layer 140 to expose regions of the planarization layer 140 at a boundary between pixels.

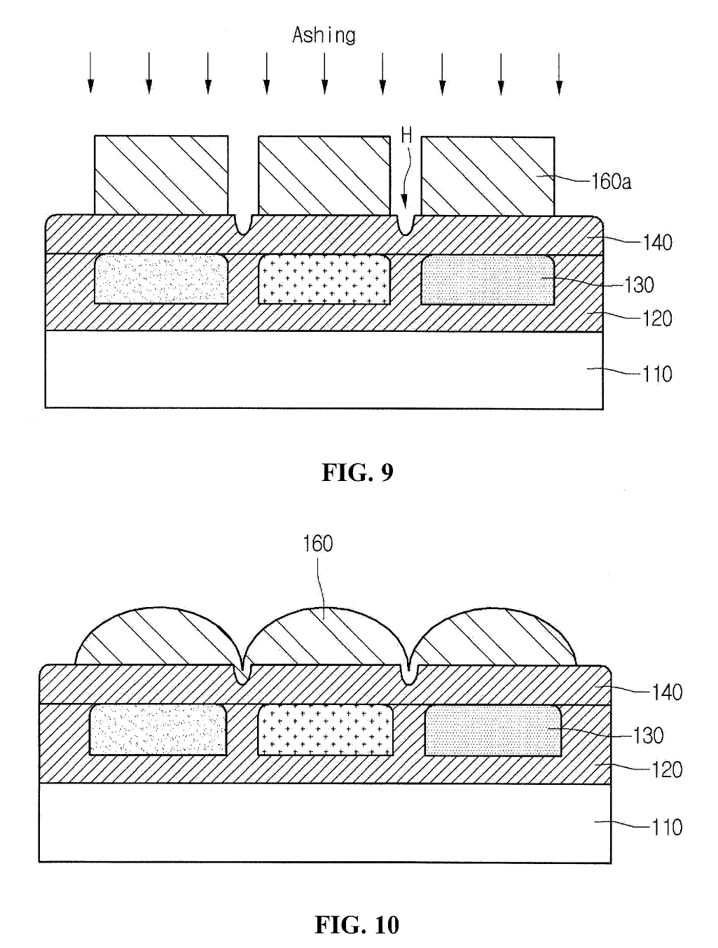

As shown in FIG. 9, the groove H is formed in the boundary between pixels of the planarization layer 140 by performing an ashing process with respect to the photoresist layer pattern 160a for a microlens.

Differently from the general photoresist layer, the photoresist layer pattern 160a for a microlens is not damaged by the ashing process.

As shown in FIG. 10, after forming the groove H in the planarization layer at the boundary between pixels, the photoresist layer pattern 160a for a microlens is reflowed to fill the groove H, thereby forming the microlens 160 on the planarization layer 140.

According to the image sensor and the image sensor manufacturing method of the embodiments, a groove is formed in the planarization layer at a pixel boundary, so that the bridge formation between microlenses can be inhibited and the gap between the microlenses can be minimized. Thus, image quality can be inhibited from being degraded due to a noise signal.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a photodiode and circuitry on a substrate arranged according to unit pixels;
a color filter layer on the substrate and comprising color filters corresponding to each photodiode;
a planarization layer on the color filter layer having a groove in a boundary between pixels; and
a microlens on the planarization layer, wherein an edge region of the microlens fills the groove.

2. A method for manufacturing an image sensor, comprising:
forming a photodiode and circuitry on a substrate arranged according to unit pixels;
forming a color filter layer on the substrate;
forming a planarization layer on the color filter layer;
forming a groove in the planarization layer at a boundary between pixels; and
forming a microlens on the planarization layer, where a portion of the microlens fills the groove.

3. The method according to claim 2, wherein forming the groove comprises using a general photoresist layer pattern.

4. The method according to claim 3, wherein forming the groove comprises forming the general photoresist layer pattern on the planarization layer, exposing regions of the planarization layer at the boundary between the pixels.

5. The method according to claim 4, wherein forming the groove further comprises ashing the general photoresist layer pattern after forming the general photoresist layer pattern.

6. The method according to claim 5, wherein ashing the general photoresist layer pattern comprises using O₂ plasma.

7. The method according to claim 5, wherein the groove is formed at the boundary between pixels of the planarization layer by performing the ashing process with respect to the general photoresist layer pattern.

8. The method according to claim 4, wherein forming the microlens comprises forming a photoresist layer pattern for a microlens on the planarization layer having the groove.

9. The method according to claim 8, wherein forming the microlens further comprises reflowing the photoresist layer pattern for the microlens such that reflown photoresist fills the groove, thereby forming the microlens on the planarization layer.

10. A method for manufacturing an image sensor, comprising:
forming a photodiode and circuitry on a substrate arranged according to unit pixels;
forming a color filter layer on the substrate;
forming a planarization layer on the color filter layer;
forming a groove in the planarization layer at a boundary between pixels; and
forming a microlens on the planarization layer, where a portion of the microlens fills the groove,
wherein forming the groove comprises using a photoresist layer pattern for a microlens.

11. The method according to claim 10, wherein forming the groove comprises forming the photoresist layer pattern for a microlens on the planarization layer, exposing regions of the planarization layer at the boundary between the pixels.

12. The method according to claim 11, wherein forming the groove further comprises ashing the photoresist layer pattern for a microlens.

13. The method according to claim 12, wherein forming the microlens comprises reflowing the photoresist layer pattern for a microlens such that reflown photoresist fills the groove.

14. The method according to claim 12, wherein the photoresist layer pattern for a microlens is not damaged by the ashing process.

15. The method according to claim 12, wherein the groove is formed at the boundary between pixels of the planarization layer by performing the ashing process with respect to the photoresist layer pattern for a microlens.
